(19) United States
(12) Patent Application Publication
(10) Pub. No.: US 2025/0157065 A1
(43) Pub. Date: May 15, 2025

(54) APPARATUS AND METHOD FOR MEASURING A BRUSH

(71) Applicant: Samsung Electronics Co., Ltd., Suwon-si (KR)

(72) Inventors: Yong Hee LEE, Suwon-si (KR); Jae Hong CHO, Suwon-si (KR); Sun Ho KIM, Suwon-si (KR); Bong Ki PARK, Suwon-si (KR); Byung Chul SONG, Suwon-si (KR)

(21) Appl. No.: 18/661,638

(22) Filed: May 12, 2024

(30) Foreign Application Priority Data
Nov. 15, 2023 (KR) 10-2023-0158377

(51) Int. Cl. G06T 7/521; A46B 9/02; A46B 13/00; A46B 13/02; B08B 1/12; B08B 1/34; B08B 13/00

(52) U.S. Cl. CPC G06T 7/521; A46B 9/026; A46B 13/001; A46B 13/02; B08B 1/12; B08B 1/34; B08B 13/00; A46B 2200/3073; G06T 2207/30148

(57) ABSTRACT

Provided is an apparatus for measuring a brush that measures shapes of nodules included in the brush and manages specifications of the nodules. The apparatus includes a rotating unit configured to rotate the brush, a sensor unit spaced apart from the brush in a second direction intersecting the first direction, a horizontal drive unit configured to move the sensor unit in the first direction; and a controller configured to control at least one of the sensor unit, the rotating unit, and the horizontal drive unit. The brush includes a first row including nodules spaced apart from each other in the first direction. The controller is configured to control the sensor unit and the horizontal drive unit such that while the horizontal drive unit moves the sensor unit in the first direction, the sensor unit performs first measurement of a shape of each of the nodules included in the first row.

### CROSS-REFERENCE TO RELATED APPLICATION

This application claims priority under 35 U.S.C. § 119 from Korean Patent Application No. 10-2023-0158377, filed on Nov. 15, 2023, in the Korean Intellectual Property Office, and all the benefits accruing therefrom under 35 U.S.C. § 119, the contents of which in its entirety are herein incorporated by reference.

### BACKGROUND

### Technical Field

The present disclosure relates to an apparatus and method for measuring a brush.

### Description of Related Art

In the semiconductor industry, development of integration technology is becoming increasingly rapid, and as a result, a step size of each of various film materials formed on a wafer is increasing, making it difficult to proceed with stable processes and secure a yield. To solve this problem, planarization technology has recently been in the spotlight. In this regard, chemical mechanical polishing (CMP) technology as the planarization technology has been widely applied, and a level of the polishing technology has a direct impact on semiconductor yield and quality.

Equipment used in this CMP process largely includes a polishing apparatus and a wafer cleaning apparatus. The wafer cleaning apparatus is used to remove slurry residue and other particles remaining on the polished wafer.

### SUMMARY

A purpose of the present disclosure is to provide an apparatus for measuring a brush that may measure shapes of all nodules included in the brush and manage specifications of the nodules.

Another purpose of the present disclosure is to provide a method for measuring a brush that may measure shapes of all nodules included in the brush and manage specifications of the nodules.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided an apparatus for measuring a brush comprising a rotating unit configured to rotate the brush extending in a first direction, a sensor unit disposed so as to be spaced apart from the brush in a second direction intersecting the first direction, a horizontal drive unit configured to move the sensor unit in the first direction; and a controller configured to control at least one of the sensor unit, the rotating unit, and the horizontal drive unit, wherein the brush includes a first row including a first plurality of nodules arranged so as to be spaced apart from each other in the first direction, and wherein the controller is configured to control the sensor unit and the horizontal drive unit such that while the horizontal drive unit moves the sensor unit in the first direction, the sensor unit performs first measurement of a shape of each of the plurality of nodules included in the first row.

According to another aspect of the present disclosure, there is provided an apparatus for measuring a brush comprising a chamber including a cleaning area and a measurement area, a rotating unit configured to rotate the brush extending in a first direction, a drive unit configured to move the brush between the cleaning area and the measurement area, a sensor unit installed in the measurement area and spaced apart from the brush in a second direction intersecting the first direction, a horizontal drive unit installed in the measurement area and configured to move the sensor unit in the first direction and a controller configured to control at least one of the sensor unit, the rotating unit, the drive unit, and the horizontal drive unit, wherein the brush includes a first row including a first plurality of nodules arranged so as to be spaced apart from each other in the first direction, wherein in the cleaning area, the brush rotates to perform a cleaning process to clean a substrate, and wherein in the measurement area, the sensor unit is configured to perform a first measurement of a shape of each of the first plurality of nodules included in the first row of the brush while the sensor unit is moving in the first direction.

According to still another aspect of the present disclosure, there is provided an apparatus for measuring a brush comprising a rotating unit configured to rotate the brush extending in a first direction, a sensor unit disposed so as to be spaced apart from the brush in a second direction intersecting the first direction, a horizontal drive unit configured to move the sensor unit in the first direction, a controller configured to control at least one of the sensor unit, the rotating unit, and the horizontal drive unit, an image processor configured to generate an image of a shape measured by the sensor unit and a storage for storing therein the image generated by the image processor, wherein the brush includes a first row including a first plurality of nodules arranged so as to be spaced apart from each other in the first direction, and includes a second row including a second plurality of nodules arranged so as to be spaced apart from each other in the first direction, wherein the first row is spaced from the second row by a first distance, wherein the sensor unit performs a first measurement of a shape of each of the first plurality of nodules included in the first row while moving in the first direction under an operation of the horizontal drive unit, wherein after the first measurement has been completed, the rotating unit rotates the brush by the first distance, wherein after the brush has rotated by the first distance, the sensor unit performs second measurement of a shape of each of the second plurality of nodules included in the second row, wherein the first measurement includes measuring, by the sensor unit, the shape of each of the first plurality of nodules included in the first row while the sensor unit is moving from a first point to a second point, wherein after the first measurement has been completed, the sensor unit returns from the second point to the first point, wherein after the sensor unit has returned to the first point, the sensor unit performs the second measurement, wherein the second measurement includes measuring, by the sensor unit, the shape of each of the second plurality of nodules included in the second row while the sensor unit is moving from the first point to the second point, wherein the image processor is configured to generate a first image of each of the first row and the second row measured by the sensor unit, wherein the first image includes a first area corresponding to an image of each of the first plurality of nodules, and a second area corresponding to an image of a surface of the brush, wherein the image processor is configured to generate a second image as an image of a cross-section of each of the first plurality of nodules taken in a vertical direction of the first area, wherein the second image includes a first reference line and is divided into a third area and a fourth area based on the first reference line, wherein the image processor is further configured to calculate a first area size value of the third area, and wherein the storage stores therein the first image, the second image, and the first area size value of the third area.

### BRIEF DESCRIPTION OF DRAWINGS

The above and other aspects and features of the present disclosure will become more apparent by describing in detail some embodiments thereof with reference to the attached drawings, in which:

FIG. 1 is a diagram for illustrating an apparatus for measuring a brush according to example embodiments of the present disclosure.

FIG. 2 is a front view of the apparatus for measuring the brush in FIG. 1.

FIG. 3 is a top view of the apparatus for measuring the brush in FIG. 1.

FIG. 4 is a side view of the apparatus for measuring the brush in FIG. 1.

FIG. 5 is a diagram for illustrating an apparatus for measuring a brush according to example embodiments of the present disclosure.

FIG. 6 is a diagram for illustrating a method for measuring the brush by the sensor unit.

FIGS. 7 to 11 are diagrams for illustrating the apparatus of FIG. 5.

FIG. 12 and FIG. 13 are diagrams for illustrating an apparatus for measuring a brush according to example embodiments of the present disclosure.

FIG. 14 and FIG. 15 are diagrams for illustrating a method for measuring a brush according to example embodiments of the present disclosure.

### DETAILED DESCRIPTIONS

Terms “first”, “second” and the like are used herein to describe various elements or components, but these elements or components are not limited by these terms. These terms are used only to distinguish one element or component from another element or component. Therefore, a first element or component mentioned below may be a second element or component within the technical spirit of the present disclosure.

In addition, in the present specification, the term “same” refers to the meaning including not only the completely same, but also a fine difference that may occur due to a margin in a process or the like.

Hereinafter, embodiments of the present disclosure are described in detail with reference to the attached drawings.

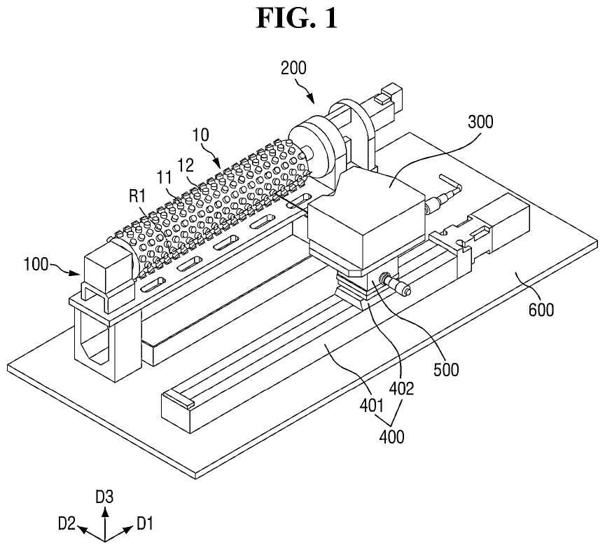

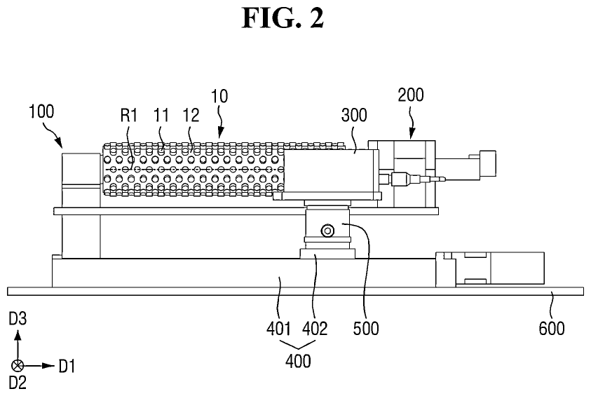

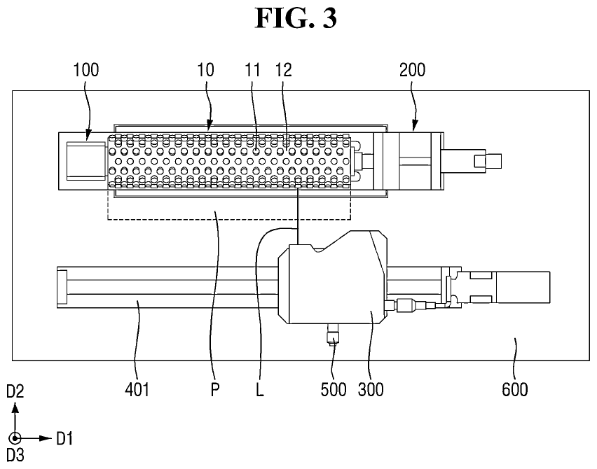

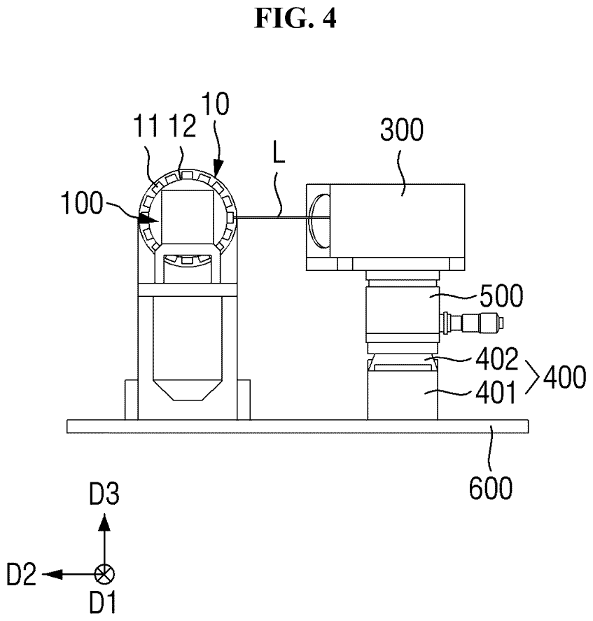

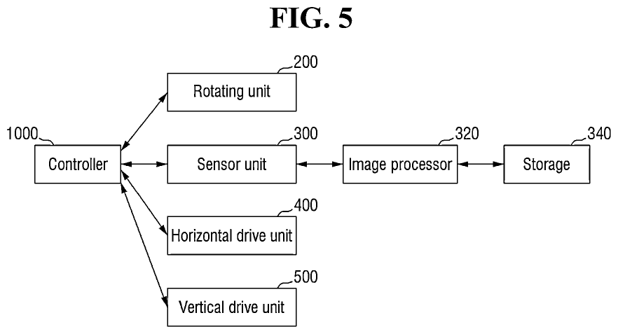

FIG. 1 is a diagram for illustrating an apparatus for measuring brush according to example embodiments of the present disclosure. FIG. 2 is a front view of the apparatus for measuring the brush in FIG. 1. FIG. 3 is a top view of the apparatus for measuring the brush in FIG. 1. FIG. 4 is a side view of the apparatus for measuring the brush in FIG. 1. FIG. 5 is a diagram for illustrating an apparatus for measuring a brush according to example embodiments of the present disclosure.

Referring to FIGS. 1 to 5, the apparatus for measuring the brush according to example embodiments of the present disclosure may include a support unit 100, a rotating unit 200, a sensor unit 300, a horizontal drive unit 400, a vertical drive unit 500, a plate 600, a controller 1000, an image processor 320, and storage 340.

The support unit 100 may be coupled to one side end of the brush 10. The support unit 100 may include one or more bearings. The support unit 100 may support the brush 10 so that the brush 10 can rotate.

In FIGS. 1 to 4, a shape of the support unit 100 is shown as a rectangular parallelepiped or a cube. However, embodiments of the present disclosure are not limited thereto. The support unit 100 may have various shapes to support the brush 10.

The brush 10 may be formed so as to extend lengthwise in a first direction D1. The brush 10 may include a cylindrical body 12 and a plurality of nodules 11 formed on the body 12. For example, the brush 10 may include a first row R1 including a plurality of nodules 11 arranged so as to be spaced apart from each other in the first direction D1. The brush 10 may include a plurality of rows, each row including a plurality of nodules 11 arranged so as to be spaced apart from each other in the first direction D1. The plurality of rows may be disposed to encircle the brush 10.

A material of the brush 10 may be polyvinyl alcohol (PVA), or polyvinyl chloride (PVC). The brush 10 may be made of a porous material. The brush 10 may be used to clean by-products remaining on a substrate after the CMP process. During this cleaning process, a shape of the nodules 11 included in the brush 10 may change. The nodules 11 may have a cylindrical shape protruding from the body 12. However, embodiments of the present disclosure are not limited thereto. The brush 10 may clean the substrate. In this case, a cross section of the nodules 11 that comes into contact with the substrate may be a cross section in the second direction D2. Therefore, after cleaning the substrate, the cross section of the nodules 11 in the second direction D2 may change. In the cleaning process of cleaning the substrate, it is necessary to secure data on the shape of the nodules 11 in order to handle a cleaning amount of the substrate.

The rotating unit 200 may be coupled to the other side end of the brush 10. The rotating unit 200 may be configured to rotate the brush 10. The rotating unit 200 may rotate the brush 10 by 360 degrees. The rotating unit 200 may rotate the brush 10 to adjust a distance between the brush and the sensor unit 300, which will be described later. A vertical level of the first row R1 including the plurality of nodules 11 may be adjusted by the rotating unit 200 rotating the brush 10.

The sensor unit 300 may be disposed to be spaced apart from the brush 10 in a second direction D2. The second direction D2 may intersect the first direction D1. The first direction D1, the second direction D2, and a third direction D3 may intersect each other. The first direction D1, the second direction D2, and the third direction D3 may be perpendicular to each direction. The first direction D1 and the second direction D2 may be horizontal directions, and the third direction D3 may be a vertical direction.

The sensor unit 300 may measure the nodules 11 included in the brush 10. For example, the sensor unit 300 may measure the shape of the nodules 11 based on a scanning result of the first row R1 including the plurality of nodules 11.

The sensor unit 300 may include a laser element. The laser element of the sensor unit 300 may emit laser L in a parallel manner to an imaginary plane P defined by the first direction D1 and the second direction D2. Thus, the sensor unit 300 may measure the plurality of nodules 11 included in the first row R1.

The horizontal drive unit 400 may include a rail 401 extending in the first direction D1 and a movable unit 402.

The rail 401 may be formed to extend lengthwise in the first direction D1. The rail 401 may be installed to be spaced apart from the brush 10 in the second direction D2. The rail 401 may extend in parallel to brush 10. The rail 401 may extend in parallel to the first row R1 including the plurality of nodules 11.

The movable unit 402 may be installed on the rail 401. The movable unit 402 may move horizontally in the first direction D1 along the rail 401. The movable unit 402 includes a motor and may move left and right at a constant speed.

The sensor unit 300 may be installed on the movable unit 402. The movable unit 402 may move the sensor unit 300. For example, the movable unit 402 may move the sensor unit 300 in the first direction D1 in a parallel manner to an extension direction of the brush. When seen from a front view, the movable unit 402 may move left and right along the rail 401 in a parallel manner to an extension direction of the brush 10 (e.g., the first direction D1) while maintaining a constant speed. As the movable unit 402 moves at a constant speed, the sensor unit 300 installed on the movable unit 402 may move together therewith.

The vertical drive unit 500 may be connected to the sensor unit 300. The vertical drive unit 500 may be installed under the sensor unit 300. The vertical drive unit 500 may be installed on the movable unit 402. The vertical drive unit 500 may be connected to the movable unit 402.

The vertical drive unit 500 may vertically move the sensor unit 300. A vertical level of the sensor unit 300 may be adjusted by the vertical drive unit 500. For example, a level of the sensor unit 300 may be adjusted in the third direction D3 by the vertical drive unit 500. The vertical level of the sensor unit 300 may be adjusted by the vertical drive unit 500 so that a vertical level of the first row R1 and the vertical level of the sensor unit 300 are equal to each other.

The support unit 100, the rotating unit 200, the sensor unit 300, the horizontal drive unit 400, and the vertical drive unit 500 may be installed on the plate 600. The support unit 100 and the rotating unit 200 connected to the brush 10 may be installed on the plate 600. The sensor unit 300, the horizontal drive unit 400, and the vertical drive unit 500 may be installed on the plate 600 so as to be spaced apart from the brush 10.

The plate 600 may extend in parallel to the first direction D1 and the second direction D2. The plate 600 may be perpendicular to the third direction D3. The vertical level of the first row R1 including the plurality of nodules 11 and the vertical level of the sensor unit 300 with respect to the plate 600 may be equal to each other.

The controller 1000 may control the rotating unit 200, the sensor unit 300, the horizontal drive unit 400, and the vertical drive unit 500.

The controller 1000 may control the rotating unit 200 to rotate the brush 10. The controller 1000 may control the sensor unit 300 to measure the brush 10. The controller 1000 may control the sensor unit 300 to scan the first row R1 including the plurality of nodules 11 of the brushes 10. The controller 1000 may control the horizontal drive unit 400 to move the sensor unit 300 in the first direction D1. The controller 1000 may control the vertical drive unit 500 to adjust the vertical level of the sensor unit 300.

The image processor 320 may be connected to the sensor unit 300 wirelessly or in a wired manner. The image processor 320 may generate an image of the nodule 11 or the first row R1 including plurality of nodules 11 measured by the sensor unit 300. After the sensor unit 300 measures an entire area of the brush 10, an image of the entire area of the brush 10 may be generated by the image processor 320. The image generated by the image processor 320 may be stored in the storage 340.

Although not illustrated, the controller 1000 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 1000 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller 1000 can include antennas, network interfaces that provide wireless and/or wire line digital and/or analog interface to one or more networks over one or more network connections (not shown), a power source that provides an appropriate alternating current (AC) or direct current (DC) to power one or more components of the controller 1000, and a bus that allows communication among the various disclosed components of the controller 1000.

The storage 340 may be any suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where the image generated by the image processor 320 can be stored.

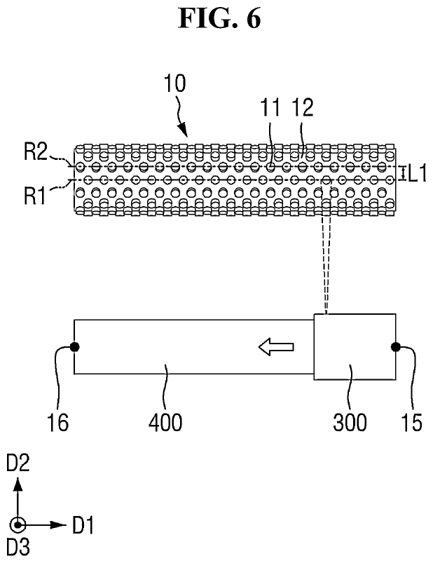

FIG. 6 is a diagram for illustrating a method for measuring the brush by the sensor unit 300. For convenience of description, descriptions of contents duplicate with those as described above with reference to FIGS. 1 to 5 are not repeated.

Referring to FIG. 6, the brush 10 may include the first row R1 including a plurality of nodules 11 and a second row R2 including a plurality of nodules 11. The second row R2 may be spaced apart from the first row R1. The first row R1 and the second row R2 may be spaced from each other by a first distance L1.

The sensor unit 300 may be horizontally moved from right to left from a first point 15 to a second point 16 by the horizontal drive unit 400. The sensor unit 300 may measure the brush 10 while moving from the first point 15 to the second point 16.

The sensor unit 300 may perform first measuring of shapes of the plurality of nodules 11 included in the first row R1 while moving from the first point 15 to the second point 16. The sensor unit 300 may perform second measuring of shapes of the plurality of nodules 11 included in the second row R2 while moving from the first point 15 to the second point 16.

After the sensor unit 300 has performed the first measuring of the shapes of the nodules 11 included in the first row R1, the rotating unit 200 may rotate the brush 10 by the first distance L1. Subsequently, the sensor unit 300 may perform the second measuring of the shapes of the plurality of nodules 11 included in the second row R2.

After performing the first measurement of measuring the shape of the nodule 11 included in the first row R1 while moving from the first point 15 to the second point 16, the sensor unit 300 may return from the second point 16 to the first point 15. After the sensor unit 300 has returned to the first point 15, the sensor unit 300 may perform the second measurement to measure the shapes of the plurality of nodules 11 included in the second row R2.

While or after the sensor unit 300 returns from the second point 16 to the first point 15, the rotating unit 200 may rotate the brush 10. For example, while the sensor unit 300 is returning to the first point 15, or after the sensor unit 300 has returned to the first point 15, the brush 10 may rotate by the first distance L1. As the brush 10 rotates by the first distance L1, a measurement target of the sensor unit 300 may change from the first row R1 to the second row R2.

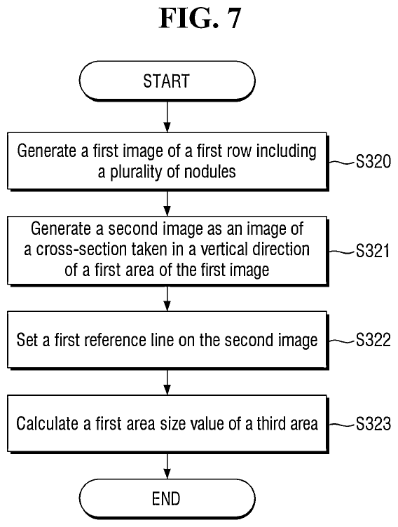

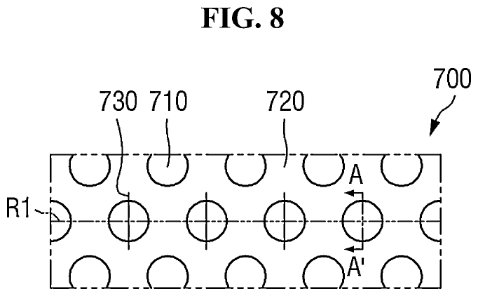

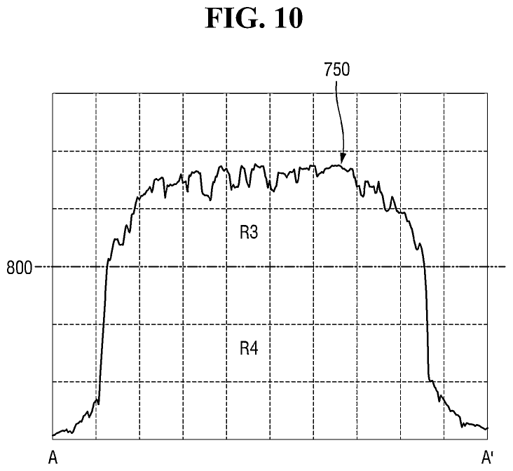

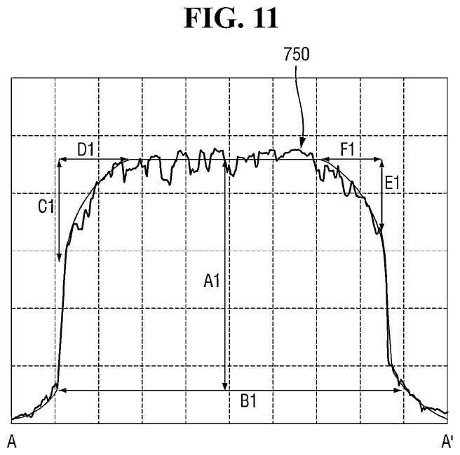

FIGS. 7 to 11 are diagrams for illustrating the image processor in FIG. 5. FIG. 7 is a flowchart of a method in which the image processor 320 generates an image. FIGS. 8 to 11 show images generated by the image processor 320. FIG. 10 and FIG. 11 are cross-sectional views cut along A-A′.

Referring to FIGS. 6 to 9, the image processor forms the first image of the first row including the plurality of nodules 11 in operation S320.

When the sensor unit 300 measures and scans the first row R1 while moving in the first direction D1, the image processor 320 may generate a first image 700 of the first row R1 including the plurality of nodules 11 (see FIG. 8).

The first image 700 may include a first area 710 and a second area 720. The first area 710 may be an image of the nodules 11. The second area 720 may be an image of the body 12 as a surface of the brush 10.

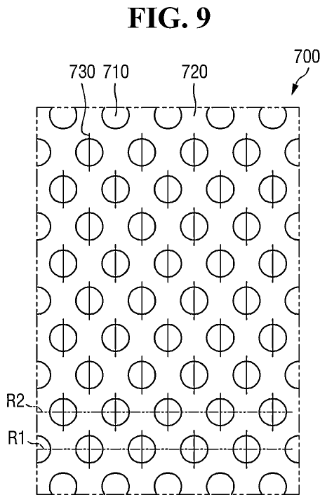

The sensor unit 300 may measure the first row R1 including the plurality of nodules 11 while moving in the first direction D1. The image processor 320 may generate an image of the shape of the first row R1. Subsequently, while the sensor unit 300 moves in the first direction D1, the sensor unit 300 may measure the second row R2 including the plurality of nodules 11. The image processor 320 may generate an image of the shape of the second row R2. Although not shown, while the sensor unit 300 moves in the first direction D1, the sensor unit 300 may measure an N-th row including the plurality of nodules 11. The image processor 320 may generate an image of a shape of the N-th row. In this way, the sensor unit 300 may measure the plurality of rows included in the brush 10, and the image processor 320 may generate an image of a shape of a plurality of rows. Therefore, the image processor 320 may generate an image of the entire area of the brush 10 (see FIG. 9).

Next, a second image of a cross-section taken in a vertical direction of the first area of the first image is generated in operation S321.

The image processor 320 may draw a vertical line 730 at a center of the first area 710 showing each of the plurality of nodules 11 in the first image 700. Subsequently, the image processor 320 may generate the second image 750 along the vertical line 730. That is, the image processor 320 may generate the second image 750 of the cross-section taken in the vertical direction of the first area 710. In some embodiments, a plurality of second images 750 may be generated, where each of the second images 750 reflects a cross-section taken along the vertical line 730 of the first area 710 of a corresponding one of the plurality of nodules 11.

Next, referring to FIG. 7 and FIG. 10, a first reference line is set in the second image in operation S322.

The second image 750 is an image showing the shape of the nodule 11. A first reference line 800 may be set in the second image 750.

The second image 750 may be divided into a third area R3 and a fourth area R4 via the first reference line 800.

The third area R3 may be an area above the first reference line 800, and the fourth area R4 may be an area under the first reference line 800. For example, the third area R3 may be an upper area of the nodule 11, and the fourth area R4 may be a lower area of the nodule 11. The third area R3 may be an area where the nodule 11 is worn due to contact between the nodule 11 and the substrate. However, embodiments of the present disclosure are not limited thereto.

Next, referring to FIG. 7 and FIG. 10, the image processor calculates a first area size value of the third area R3 in operation S323.

The first area size value of the third area R3 may be calculated from the second image 750 divided into the third area R3 and the fourth area R4 via the first reference line 800.

The image processor 320 may generate the first image 700 of each of the plurality of rows included in the brush 10, and may generate the second images 750 of the cross sections taken along the vertical direction of the nodules 11 in the first image 700. For example, the image processor 320 may generate a second image 750 of the cross section taken along the vertical line 730 of each of the plurality of nodules 11 included in the brush 10. Subsequently, the image processor 320 may draw the first reference line 800 on the second image 750 and calculate the first area size value of the third area R3. The first image 700, the second image 750, and the first area size value may be stored in the storage (e.g., storage 340 in FIG. 5) for each of the plurality of nodules 11.

The first image 700, the second image 750, and the first area size value may be stored in the storage (e.g., storage 340) and may be used to manage the specification of the nodule 11. The sensor unit 300 measures the entire area of the brush 10, and the image processor 320 may generate an image of the entire area of the brush 10. Therefore, the apparatus of the present disclosure may collect and manage the data on the image and the area size of each of the nodules 11 included in the brush 10.

Referring to FIG. 11, the image processor 320 may calculate data on a length of each of the second images 750.

For example, the image processor 320 may calculate a height A1, a width B1 in the vertical direction, lengths C1 and D1 of a left top, and lengths E1 and F1 of a right top of the second image 750. The calculated data may be stored in the storage 340.

The image processor 320 may generate the second image 750 of the shape of each of the plurality of nodules 11 included in the brush 10. Then, the image processor 320 may extract, from the second images 750, the height A1, the vertical width B1, the lengths C1 and D1 of the left top, and the lengths E1 and F1 of the right top of each second image 750. Thus, the apparatus of the present disclosure may manage the specification of each of all nodules 11 included in the brush 10. For example, the height A1, the vertical width B1, the lengths C1 and D1 of the left top, and the lengths E1 and F1 of the right top of each second image 750 may be used to calculate the first area size value of the third area R3.

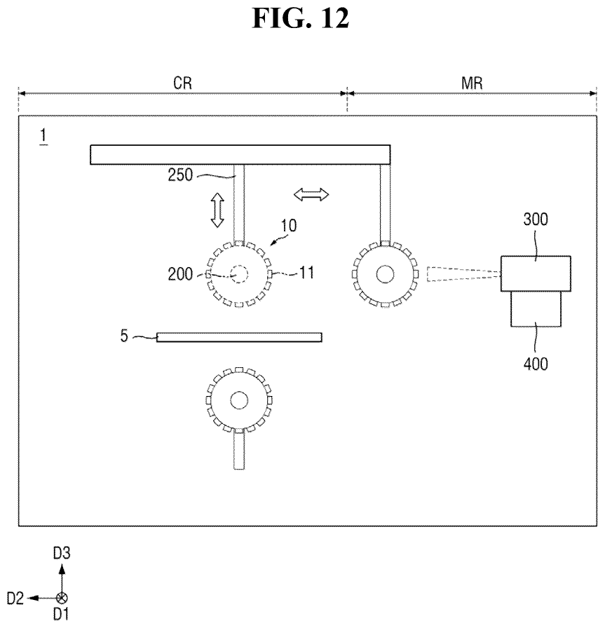

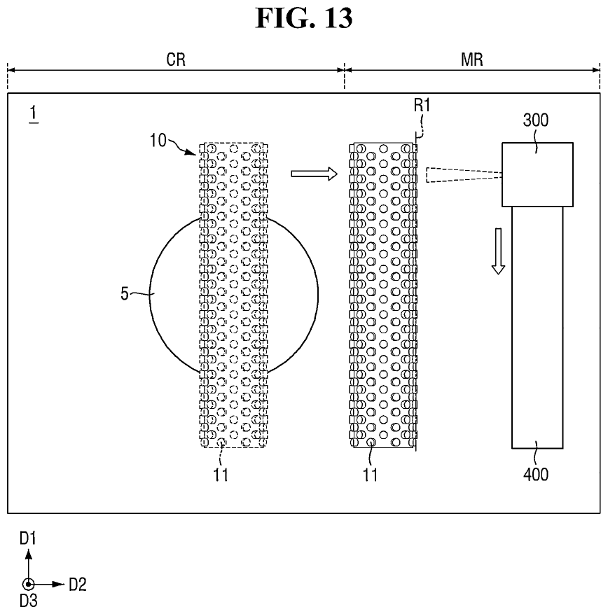

FIG. 12 and FIG. 13 are diagrams for illustrating an apparatus for measuring a brush according to example embodiments of the present disclosure. For convenience of descriptions, descriptions of contents duplicate with those as described above with reference to FIGS. 1 to 11 are not repeated.

Referring to FIG. 12 and FIG. 13, the apparatus for measuring the brush according to example embodiments of the present disclosure may include a substrate 5, the brush 10, the rotating unit 200, the drive unit 250, the sensor unit 300, and the horizontal drive unit 400 in a chamber 1 including a cleaning area CR and a measurement area MR.

The cleaning area CR may be an area where a cleaning process of cleaning the substrate 5 using the brush 10 is performed. The substrate 5, the brush 10, the rotating unit 200, and the drive unit 250 may be installed in the cleaning area CR.

The brush 10 may be formed to extend in the first direction D1. The brush 10 may include the plurality of nodules 11. The brush 10 may include the first row R1 including the plurality of nodules 11. The brush 10 may be used to clean the substrate 5. For example, as the brush 10 rotates, the nodule 11 may clean the substrate 5.

The rotating unit 200 may be connected to the brush 10. The rotating unit 200 may rotate the brush 10. The rotating unit 200 may rotate the brush 10 to clean the substrate 5. The rotating unit 200 may rotate the brush 10 around a central axis of the brush 10.

The drive unit 250 may be connected to the brush 10. The drive unit 250 may move the brush 10 vertically in the third direction D3. The drive unit 250 may move the brush 10 left and right horizontally in the second direction D2. The drive unit 250 may move the brush 10 between the cleaning area CR and the measurement area MR.

The measurement area MR may be an area in which the brush 10 is measured. Specifically, the measurement area MR may be an area in which the plurality of nodules 11 included in the brush 10 are measured.

The sensor unit 300 and the horizontal drive unit 400 may be installed in the measurement area MR.

The sensor unit 300 may be disposed to be spaced apart from the brush 10 in the second direction D2. The horizontal drive unit 400 may be disposed to be spaced apart from the brush 10 in the second direction D2. The horizontal drive unit 400 may move the sensor unit 300 in the first direction D1. The sensor unit 300 may measure the shape of each of the plurality of nodules 11 included in the first row R1 of the brush 10 while moving in the first direction D1.

The cleaning process in which the brush 10 cleans the substrate 5 and a measuring process in which the sensor unit 300 measures the shape of each of the plurality of nodules 11 included in the first row R1 are performed in an in-situ manner.

The cleaning process in which the substrate 5 is cleaned by the brush 10 may be performed in the cleaning area CR. When the cleaning process has been completed, the brush 10 may be moved from the cleaning area CR to the measurement area MR by the drive unit 250.

After the brush 10 has been moved to the measurement area MR, the shape of each of the plurality of nodules 11 included in the first row R1 may be measured by the sensor unit 300. For example, the sensor unit 300 may measure and scan the first row R1 while moving at a constant speed in the first direction D1 under an operation of the horizontal drive unit 400.

When the substrate is chemically and mechanically polished in the CMP (Chemical Mechanical Polishing) process, by-products are inevitably produced. To remove the by-products, contaminants on a surface of the substrate are removed using the brush. The brush 10 includes the body 12 and the nodules 11. The brush 10 rotates to clean the substrate 5. During the process of cleaning the substrate, the nodules 11 come into contact with the substrate 5. During the substrate cleaning process, the shape of the nodules 11 may be changed due to contact pressure with the substrate 5. As the shape of the nodules 11 are changed, the substrate cleaning performance may vary. Therefore, it is necessary to obtain the data on the shape of the nodules 11 and quantify the specification of the shape of the nodules 11.

Conventionally, in order to measure the cross-sectional shape of the brush 10, the brush 10 is cut and the shape of the nodules 11 included in the brush 10 are measured. In other words, in order to measure the shape of each of the nodules 11 arranged in the entire area of the brush 10, there is no choice but to perform a destructive test. However, as product difficulty increases and processes and materials diversify, a non-destructive measuring apparatus is needed that may measure all nodules 11 without cutting the brush 10.

However, the apparatus for measuring the brush 10 according to example embodiments of the present disclosure may include the rotating unit 200 configured to rotate the brush 10, the sensor unit 300 disposed so as to be spaced apart from the brush 10 in the second direction D2, the horizontal drive unit 400 configured to move the sensor unit 300 in the first direction D1, the controller 1000 that controls at least one of the sensor unit 300, the rotating unit 200, and the horizontal drive unit 400, and the image processor 320 that is configured to generate the image of the shape measured by the sensor unit 300.

The sensor unit 300 may measure the first row R1 including the plurality of nodules 11 included in the brush 10. The rotating unit 200 may rotate the brush 10, and then the sensor unit 300 may measure the second row R2 including the plurality of nodules 11. The image processor 320 may generate the first images 700 of each of the first row R1 and the second row R2 measured by the sensor unit 300 and the second images 750 of the vertical cross section of the nodules 11 in the first images 700. The image processor 320 may calculate the first area size value of the third area R3 in the second images 750. Subsequently, the first images 700, the second images 750, and the first area size values may be stored in the storage 340.

In the above process, the apparatus may measure the entire area of the brush 10 without cutting the brush 10. That is, the shape of each of all nodules 11 included in the brush 10 may be measured. The specification of the nodule 11 may be managed based on the data on the shape of each of the nodules 11 included in the brush 10. Based on data on the shape of the nodule 11, the nodule 11 may be processed into the user's desired shape using an aging apparatus that wears the nodule 11.

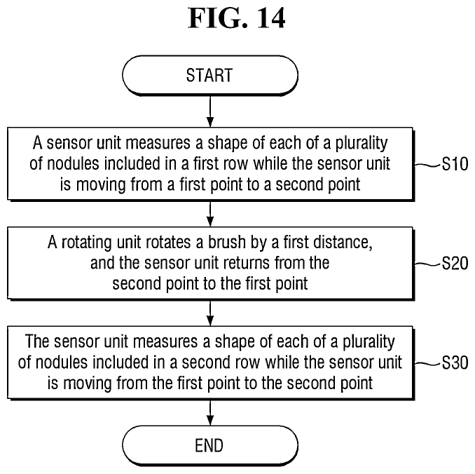

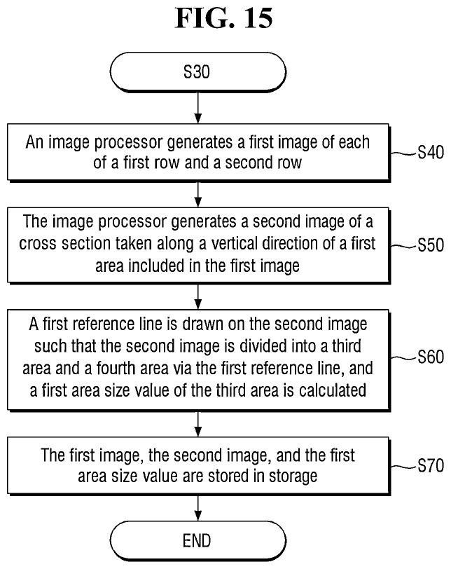

FIG. 14 and FIG. 15 are diagrams for illustrating a method for measuring a brush according to example embodiments of the present disclosure.

Referring to FIG. 1 and FIG. 14, the apparatus for measuring the brush including the rotating unit 200 configured to rotate the brush 10 extending in the first direction D1, the sensor unit 300 disposed so as to be spaced apart from the brush 10 in the second direction D2, and the horizontal drive unit 400 configured to move the sensor unit 300 in the first direction D1 may be provided.

First, while the sensor unit 300 moves from the first point (e.g., first point 15) to the second point (e.g., second point 16), the sensor unit 300 measures the shape of each of the plurality of nodules (e.g., nodules 11) included in the first row (e.g., first row R1) in operation S10.

The brush 10 may include the plurality of nodules 11 and the plurality of rows, each row including the plurality of nodules 11. For example, the brush 10 may include the first row R1 including the plurality of nodules 11 arranged so as to be spaced apart from each other in the first direction D1. The brush 10 may include the second row R2 including the plurality of nodules 11 arranged so as to be spaced apart from each other in the first direction D1. The first row R1 and the second row R2 may be spaced from each other by the first distance L1.

The sensor unit 300 may measure the shape of each of the plurality of nodules 11 included in the first row R1 while moving at a constant speed from the first point 15 to the second point 16 in the first direction D1 under the operation of the horizontal drive unit 400.

Next, the rotating unit rotates the brush by the first distance (e.g., first distance L1) and the sensor unit (e.g., sensor unit 300) moves from the second point (e.g., second point 16) to the first point (e.g., first point 15) in operation S20.

After the sensor unit 300 has measured the shape of each of the plurality of nodules 11 included in the first row R1, the rotating unit 200 may rotate the brush 10 by the first distance L1 such that the sensor unit 300 measures the plurality of nodules 11 included in the second row R2. In this regard, in order to measure the plurality of nodules 11 included in the second row R2, the sensor unit 300 may move from the second point 16 to the first point 15 again.

Next, while the sensor unit 300 moves from the first point (e.g., first point 15) to the second point (e.g., second point 16), the sensor unit (e.g., sensor unit 300) measures the shape of each of the plurality of nodules (e.g., nodules 11) included in the second row in operation S30.

After the sensor unit 300 has measured the shape of each of the plurality of nodules 11 included in the first row R1, the shape of each of the plurality of nodules 11 included in the second row R2 may be measured by the sensor unit 300. The sensor unit 300 may measure the plurality of rows included in the brush 10 and thus measure the shapes of all of the nodules 11 in the entire area of the brush 10.

Referring to FIG. 15, the apparatus for measuring the brush (e.g., brush 10) may further include the image processor 320 and the storage 340. After the sensor unit (e.g., sensor unit 300) has measured the plurality of nodules (e.g., nodules 11) included in the first row (e.g., row R1) and the second row (e.g., row R2) in operations S10, S20, and S30, the image processor (e.g., image processor 320) generates the first image (e.g., first image 700) of each of the first row (e.g., row R1) and the second row (e.g., row R2) in operation S40.

The image processor 320 may generate the first image 700 of each of the first row R1 and the second row R2, each including the plurality of nodules 11, as shown in FIG. 8 and FIG. 9. The first images 700 may include the first area 710 which is the image of the nodules 11, and the second area 720 which is the image of the body 12.

Next, the image processor 320 generates the second images 750 of the cross sections taken along the vertical direction of the first area included in the first images 700 in operation S50.

As described in FIG. 8 and FIG. 9, the image processor 320 may find a center of the first area 710 in the first image 700. The image processor 320 may draw the vertical line 730 passing through the center of the first area 710. For example, the image processor 320 may draw the vertical line 730 through the center of each of the plurality of nodules 11 of the first area 710. The image processor 320 may generate the second images 750 showing the cross-sections taken in the vertical direction through the center of each of the plurality of nodules 11 of the first area 710 based on the vertical line 730.

Next, the first reference line (e.g., first reference line 800) is drawn on the second image (e.g., second image 750). The second image (e.g., second image 750) is divided into the third area (e.g., third area R3) and the fourth area (e.g., fourth area R4) via the first reference line (e.g., first reference line 800). The first area size value of the third area (e.g., third area R3) is calculated in operation S60. Next, the first image (e.g., first image 700), the second image (e.g., second images 750), and the first area size value are stored in the storage in operation S70.

As described in FIG. 10, the image processor 320 divides the second image 750 into the third area R3 and fourth area R4 via the first reference line 800 drawn on the second image 750. The third area R3 may be an area located above the first reference line 800. The fourth area R4 may be an area located under the first reference line 800.

The image processor 320 calculates the first area size value of the third area R3. The first area size value of the third area R3 may change as the nodule 11 is worn in contact with the substrate. The first image 700, the second image 750, and the first area size value extracted using the image processor 320 may be stored in the storage 340.

In example embodiments, when a first area size value of the third area R3 is smaller than a threshold value, the controller 1000 may determine that the nodule 11 is worn and may notify a user to replace the brush 10. In other example embodiments, when the first area size values of the third areas R3 of a predetermined number of nodules 11 are smaller than the threshold value, the controller 1000 may determine that the nodule 11 is worn and may notify a user to replace the brush 10. In these example embodiments, the controller 1000 may prevent further operation of the chemical mechanical polishing (CMP) of the substrate 5 until the brush 10 is replaced.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An apparatus for measuring a brush, the apparatus comprising:
a rotating unit configured to rotate the brush extending in a first direction;
a sensor unit disposed so as to be spaced apart from the brush in a second direction intersecting the first direction;
a horizontal drive unit configured to move the sensor unit in the first direction; and
a controller configured to control at least one of the sensor unit, the rotating unit, and the horizontal drive unit,
wherein the brush includes a first row including a first plurality of nodules arranged so as to be spaced apart from each other in the first direction, and
wherein the controller is configured to control the sensor unit and the horizontal drive unit such that while the horizontal drive unit moves the sensor unit in the first direction, the sensor unit performs a first measurement of a shape of each of the first plurality of nodules included in the first row.

2. The apparatus for measuring the brush of claim 1,
wherein the brush further includes a second row including a second plurality of nodules arranged so as to be spaced apart from each other in the first direction, wherein the second row is spaced from the first row by a first distance, and
wherein the controller is further configured to:
after the sensor unit has measured the shape of each of the first plurality of nodules included in the first row, control the rotating unit to rotate the brush by the first distance; and
control the sensor unit to perform a second measurement of a shape of each of the second plurality of nodules included in the second row.

3. The apparatus for measuring the brush of claim 2,
wherein the first measurement includes measuring, by the sensor unit, the shape of each of the first plurality of nodules included in the first row while the sensor unit is moving from a first point to a second point,
wherein after the first measurement has been completed, the sensor unit returns from the second point to the first point, and
wherein after the sensor unit has returned to the first point, the sensor unit performs the second measurement, wherein the second measurement includes measuring, by the sensor unit, the shape of each of the second plurality of nodules included in the second row while the sensor unit is moving from the first point to the second point.

4. The apparatus for measuring the brush of claim 1,
wherein an imaginary plane is defined based on the first direction and the second direction, and
wherein the sensor unit includes a laser element, and the laser element is configured to emit laser in a parallel manner to the imaginary plane to measure the first plurality of nodules included in the first row.

5. The apparatus for measuring the brush of claim 1, further comprising:
a vertical drive unit connected to the horizontal drive unit and the sensor unit and configured to move the sensor unit vertically,
wherein the vertical drive unit adjusts a vertical level of the sensor unit so that a vertical level of the first row and a vertical level of the sensor unit are equal to each other.

6. The apparatus for measuring the brush of claim 1, further comprising:
an image processor configured to generate an image of the shape of each of the first plurality of nodules measured by the sensor unit,
wherein the image processor is configured to generate a first image of the first row including the first plurality of nodules.

7. The apparatus for measuring the brush of claim 6,
wherein the first image includes a first area corresponding to an image of each of the first plurality of nodules, and a second area corresponding to an image of a surface of the brush, and
wherein the image processor is configured to generate a second image as an image of a cross-section of each of the first plurality of nodules taken in a vertical direction of the first area.

8. The apparatus for measuring the brush of claim 7, further comprising a storage for storing therein the first image and the second images.

9. The apparatus for measuring the brush of claim 7,
wherein the second image includes a first reference line and is divided into a third area and a fourth area based on the first reference line,
wherein the image processor is further configured to calculate a first area size value of the third area, and
wherein the apparatus further comprises a storage for storing therein the first image, the second images, and the first area size value.

10. The apparatus for measuring the brush of claim 1, further comprising:
a vertical drive unit connected to the horizontal drive unit and the sensor unit and configured to move the sensor unit vertically,
wherein the brush further includes a second row including a second plurality of nodules arranged so as to be spaced apart from each other in the first direction, wherein the second row is spaced from the first row by a first distance, and
wherein the controller is further configured to:
control the vertical drive unit to adjust a vertical level of the sensor unit so that a vertical level of the first row and a vertical level of the sensor unit are equal to each other;
after the sensor unit has measured the shape of each of the first plurality of nodules included in the first row, control the rotating unit to rotate the brush by the first distance; and
control the sensor unit to perform a second measurement of a shape of each of the second plurality of nodules included in the second row.

11. An apparatus for measuring a brush, the apparatus comprising:
a chamber including a cleaning area and a measurement area;
a rotating unit configured to rotate the brush extending in a first direction;
a drive unit configured to move the brush between the cleaning area and the measurement area;
a sensor unit installed in the measurement area and spaced apart from the brush in a second direction intersecting the first direction;
a horizontal drive unit installed in the measurement area and configured to move the sensor unit in the first direction; and
a controller configured to control at least one of the sensor unit, the rotating unit, the drive unit, and the horizontal drive unit,
wherein the brush includes a first row including a first plurality of nodules arranged so as to be spaced apart from each other in the first direction,
wherein in the cleaning area, the brush rotates to perform a cleaning process to clean a substrate, and
wherein in the measurement area, the sensor unit is configured to perform a first measurement of a shape of each of the first plurality of nodules included in the first row of the brush while the sensor unit is moving in the first direction.

12. The apparatus for measuring the brush of claim 11, wherein the cleaning process and the first measurement are performed in an in-situ manner.

13. The apparatus for measuring the brush of claim 11,
wherein the brush further includes a second row including a second plurality of nodules arranged so as to be spaced apart from each other in the first direction, wherein the second row is spaced from the first row by a first distance, and
wherein the controller is further configured to:
after the sensor unit has measured the shape of each of the first plurality of nodules included in the first row, control the rotating unit to rotate the brush by the first distance; and
control the sensor unit to perform a second measurement of a shape of each of the second plurality of nodules included in the second row.

14. The apparatus for measuring the brush of claim 13,
wherein the first measurement includes measuring, by the sensor unit, the shape of each of the first plurality of nodules included in the first row while the sensor unit is moving from a first point to a second point,
wherein after the first measurement has been completed, the sensor unit returns from the second point to the first point, and
wherein after the sensor unit has returned to the first point, the sensor unit performs the second measurement, wherein the second measurement includes measuring, by the sensor unit, the shape of each of the second plurality of nodules included in the second row while the sensor unit is moving from the first point to the second point.

15. The apparatus for measuring the brush of claim 11, further comprising:
a vertical drive unit connected to the horizontal drive unit and the sensor unit and configured to move the sensor unit vertically,
wherein the vertical drive unit adjusts a vertical level of the sensor unit so that a vertical level of the first row is equal to a vertical level of the sensor unit.

16. The apparatus for measuring the brush of claim 11, further comprising:
an image processor configured to generate an image of the shape of the first plurality of nodules measured by the sensor unit,
wherein the image processor is configured to generate a first image of the first row including the first plurality of nodules.

17. The apparatus for measuring the brush of claim 16,
wherein the first image includes a first area corresponding to an image of each of the first plurality of nodules, and a second area corresponding to an image of a surface of the brush, and
wherein the image processor is configured to generate a second image as an image of a cross-section of each of the first plurality of nodules taken in a vertical direction of the first area.

18. The apparatus for measuring the brush of claim 17,
wherein the second image includes a first reference line and is divided into a third area and a fourth area based on the first reference line,
wherein the image processor is further configured to calculate a first area size value of the third area, and
wherein the apparatus further comprises a storage for storing therein the first image, the second images, and the first area size value.

19. The apparatus for measuring the brush of claim 11,
wherein an imaginary plane is defined based on the first direction and the second direction, and
wherein the sensor unit includes a laser element, and the laser element is configured to emit laser in a parallel manner to the imaginary plane to measure the first plurality of nodules included in the first row.

20. An apparatus for measuring a brush, the apparatus comprising:
a rotating unit configured to rotate the brush extending in a first direction;
a sensor unit disposed so as to be spaced apart from the brush in a second direction intersecting the first direction;
a horizontal drive unit configured to move the sensor unit in the first direction;
a controller configured to control at least one of the sensor unit, the rotating unit, and the horizontal drive unit;
an image processor configured to generate an image of a shape measured by the sensor unit; and
a storage for storing therein the image generated by the image processor,
wherein the brush includes a first row including a first plurality of nodules arranged so as to be spaced apart from each other in the first direction, and includes a second row including a second plurality of nodules arranged so as to be spaced apart from each other in the first direction, wherein the first row is spaced from the second row by a first distance,
wherein the sensor unit performs a first measurement of a shape of each of the first plurality of nodules included in the first row while moving in the first direction under an operation of the horizontal drive unit,
wherein after the first measurement has been completed, the rotating unit rotates the brush by the first distance,
wherein after the brush has rotated by the first distance, the sensor unit performs a second measurement of a shape of each of the second plurality of nodules included in the second row,
wherein the first measurement includes measuring, by the sensor unit, the shape of each of the first plurality of nodules included in the first row while the sensor unit is moving from a first point to a second point,
wherein after the first measurement has been completed, the sensor unit returns from the second point to the first point,
wherein after the sensor unit has returned to the first point, the sensor unit performs the second measurement, wherein the second measurement includes measuring, by the sensor unit, the shape of each of the second plurality of nodules included in the second row while the sensor unit is moving from the first point to the second point,
wherein the image processor is configured to generate a first image of each of the first row and the second row measured by the sensor unit, wherein the first image includes a first area corresponding to an image of each of the first plurality of nodules, and a second area corresponding to an image of a surface of the brush,
wherein the image processor is configured to generate a second image as an image of a cross-section of each of the first plurality of nodules taken in a vertical direction of the first area,
wherein the second image includes a first reference line and is divided into a third area and a fourth area based on the first reference line,
wherein the image processor is further configured to calculate a first area size value of the third area, and
wherein the storage stores therein the first image, the second image, and the first area size value of the third area.
